(19) United States
(12) Patent Application Publication
(10) Pub. No.: US 2017/0366906 A1
(43) Pub. Date: Dec. 21, 2017

(54) HEARING DEVICE WITH EMBEDDED DIE STACK

(71) Applicant: Andy Lambert, Eagan, MN (US)

(72) Inventor: Andy Lambert, Eagan, MN (US)

(21) Appl. No.: 15/184,744

(22) Filed: Jun. 16, 2016

(51) Int. Cl. H04R 25/00; H01L 25/065

(52) U.S. Cl. CPC H04R 25/608; H04R 25/604; H01L 25/0657; H01L 2225/06541; H04R 2225/021

(57) ABSTRACT

Described herein are methods and apparatus in which two integrated circuit dies are stacked and embedded in a printed circuit board (PCB) substrate. In one embodiment, the two dies are stacked directly on top of one another with and electrically connected with through-silicon-vias (TSVs). The interconnect routing between the two die occurs within the TSVs and die level redistribution layer (RDL) routing. The resulting die stack can then be embedded into a single layer of the PCB substrate rather than in two separate layers.

### FIELD OF THE DISCLOSURE

This patent application pertains to electronic hearing devices, including hearing assistance devices and hearing aids, and methods for their construction.

### BACKGROUND

Hearing devices provide sound for the wearer. Some examples of hearing devices are headsets, hearing aids, speakers, cochlear implants, bone conduction devices, and personal listening devices. Hearing aids are electronic devices that compensate for hearing losses amplifying and compressing sound, usually in a frequency selective manner. The electronic components of a hearing aid may include a microphone for receiving ambient sound, processing circuitry for processing the microphone signal in a manner that depends upon the frequency and amplitude of the microphone signal, an output transducer or receiver for converting the amplified microphone signal to sound for the wearer, and a battery for powering the components. Hearing aids may also incorporate wireless transceivers for enabling communication with an external device and/or communication between two hearing instruments worn by a user. In various examples, a hearing aid is worn in and/or around a patient's ear.

Wearable hearing devices such as hearing aids are designed with a small package size to both increase comfort and provide a less conspicuous appearance. In order to achieve the smallest hearing aid designs possible there is a need to develop smaller, denser micro-electronic packaging technologies.

### BRIEF DESCRIPTION OF THE DRAWINGS

FIG. 1 shows the basic electronic components of an exemplary hearing assistance device.

FIG. 2 shows a two die stack.

FIG. 3 shows a two die stack embedded in a PCB substrate.

FIG. 4 shows a third die embedded with the two die stack in a PCB substrate.

### DETAILED DESCRIPTION

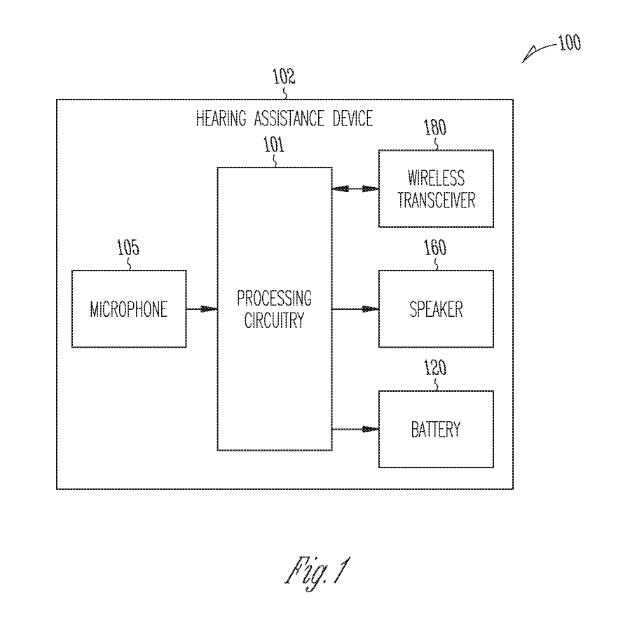

The electronic components of a hearing aid may include a microphone for receiving ambient sound, processing circuitry for amplifying the microphone signal in a manner that depends upon the frequency and amplitude of the microphone signal, a speaker for converting the amplified microphone signal to sound for the wearer, and a battery for powering the components. FIG. 1 illustrates the basic functional components of an example hearing assistance device 100 such as a hearing aid. The electronic circuitry of the device may be contained within a housing 102 that may be placed, for example, in the external ear canal or behind the ear. A microphone 105 receives sound waves from the environment and converts the sound into an input signal. The input signal may then be amplified by a pre-amplifier and sampled and digitized by an A/D converter to result in a digitized input signal. The device's processing circuitry 101 (e.g., which may include a digital signal processor or DSP) processes the digitized input signal into an output signal in a manner that compensates for the patient's hearing deficit. The processing circuitry 101 may be implemented in a variety of different ways, such as with an integrated digital signal processor or with a mixture of discrete analog and digital components that include a processor executing programmed instructions contained in a memory. The output signal is then passed to an audio output stage that drives speaker 160 (also referred to as a receiver) to convert the output signal into an audio output.

In various embodiments, the hearing assistance device electronics including the processing circuitry 101 are enclosed in a housing 102 designed to be worn behind or about the wearer's ear and the receiver is positioned in the ear or the ear canal of the wearer. In various embodiments, the processing circuitry includes a stacked die circuit for processing the microphone signal and controlling the operation of the hearing assistance device. In various embodiments, the stacked die circuit includes an integrated circuit die adapted for digital signal processing and an integrated circuit die adapted for data storage. In various embodiments, the stacked die circuit is embedded in a printed circuit board (PCB) substrate. Other die combinations are possible without departing from the scope of the present subject matter. The die combinations described herein are intended to demonstrate the present subject matter and are not intended in a limited or exclusive sense.

Previous approaches to constructing stacked die structures have included the following. In one approach, referred to as wire bond die stacking, die are stacked either all active side up or a combination of flip chip and active side up and then wire bonded to a substrate to achieve an electrical connection. The term “flip chip” denotes the flipped orientation of the active side of the silicon chip when connected to a substrate as opposed to the orientation of the active side when using wire bond connections. In flip chip designs, active pads provide connections to the active components. In another approach, which may be referred to as flip chip on flexible PCB, a die may be placed side by side on the same surface of the PCB or on opposite sides of the PCB. Another approach involves embedding a die in a PCB substrate, where the bottom die may be thinned (e.g., to around 85 micrometers), embedding the die in the PCB substrate, and then mounting another die on the top surface of the PCB. Another approach involves doubly embedding dies in the PCB substrate where two die are embedded in the PCB substrate in separate layers.

The presently described approach solves the problem of having to embed two die in two different layers of substrate to produce an embedded die stack. In this approach, two die are stacked directly on top of one another with and electrically connected with through-silicon-vias (TSVs). Through-silicon-vias are small vertical electrical connections extending through the silicon of an integrated circuit (IC). The interconnect routing between the two die occurs within the TSVs and die level redistribution layer (RDL) routing. The resulting die stack can then be embedded into a single layer of the PCB substrate rather than in two separate layers. The die stack thickness in some embodiments may be either 85 um or 150 um. Other thicknesses may also be used for embedding if compatible with a particular process technology. This technique saves additional substrate layer routing and vertical via interconnections between layers to create a high density package and increase electrical performance.

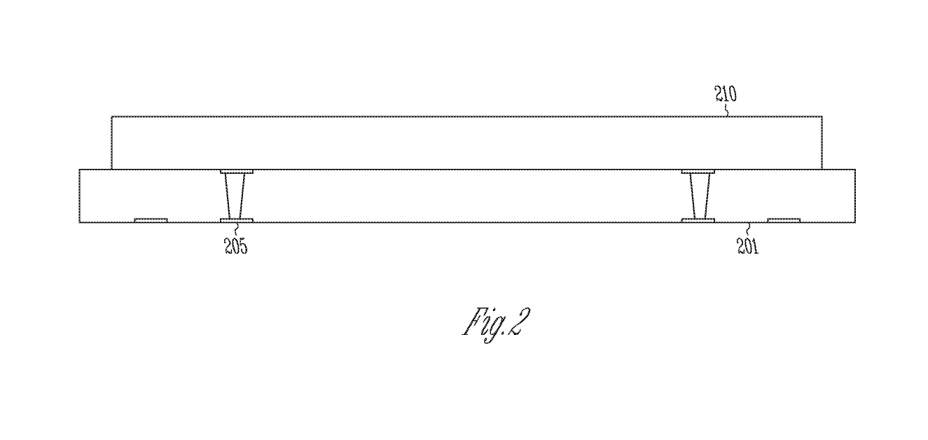

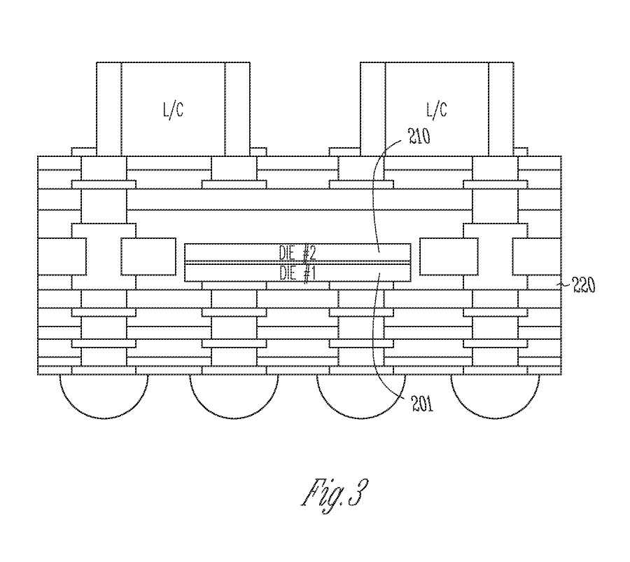

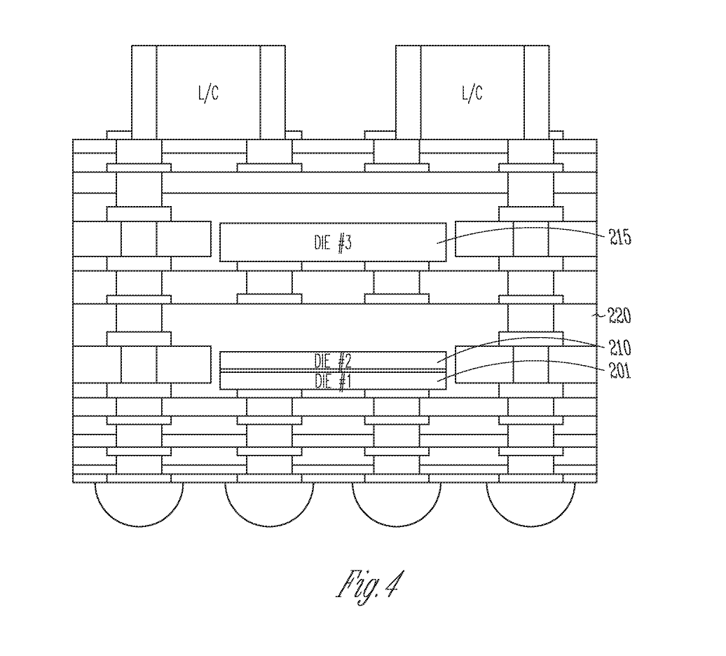

FIG. 2 shows an example of a die stack that includes a bottom die 201 with TSVs 205 and a top die 210 which is stacked on top of the bottom die 201 and electrically connected with the TSVs 205. The resulting die stack may then be embedded within a single layer of a PCB substrate 220 as shown in FIG. 3. This design reduces embedded substrate design complexity as only a single embedded layer is needed in order to embed two dies. This removes the need for routing layers and vertical via connections. Electrical performance is increased because the top and bottom die have direct electrical contact which removes the typical parasitic impedance caused by routing electrical signals in the PCB substrate. In another embodiment, if the double embedded die substrate configuration were to be used, a third die 215 may be embedded in the secondary embedding layer as shown in FIG. 4 to further increase packaging density.

In another embodiment, the dies in FIGS. 2 and 3 may placed back to back with active die side and interconnect in opposing directions and embedded in a substrate. This configuration would eliminate the need for TSVs but could increase the overall resulting circuit size because the interconnect between the two dies would need to be routed in the peripheral area outside the die which would increase the overall footprint area. Electrical performance could also be compromised due to the longer interconnect distance of the path from die to die.

### Example Embodiments

In Example 1, an electronic device, comprises: a first die; a second die; a printed circuit board (PCB) substrate; wherein the first die is stacked on top of the second die to form a die stack, wherein the first and second dies are electrically connected; and, wherein the die stack is embedded in a single first layer of the PCB substrate.

In Example 2, the subject matter of any of the Examples herein may optionally include wherein a third die is embedded in a second layer of the PCB substrate.

In Example 3, the subject matter of any of the Examples herein may optionally include wherein second die has through-silicon-vias (TSVs) incorporated therein that electrically connect the first and second dies.

In Example 4, the subject matter of any of the Examples herein may optionally include wherein the first and second dies are placed back to back with active die side and interconnect in opposing directions to electrically connect the first and second dies.

In Example 5, a method for constructing an electronic device comprises: stacking a first die is on top of a second die to form a die stack with the first and second dies electrically connected; and, embedding the die stack in a single first layer of a printed circuit board (PCB) substrate.

In Example 6, the subject matter of any of the Examples herein may optionally include embedding a third die in a second layer of the PCB substrate.

In Example 7, a hearing device, comprises: a microphone to convert an audio input into a first input signal; a telecoil to convert a time-varying electromagnetic field sensed by the telecoil into a second input signal; processing circuitry to process the first input signal, the second input signal, or a combination thereof into an output signal in a manner that compensates for the patient's hearing deficit; wherein the processing circuitry comprises a first die and a second die and wherein the first die is stacked on top of the second die to form a die stack with the first and second dies are electrically connected; and, wherein the die stack is embedded in a single first layer of a printed circuit board (PCB) substrate.

In Example 8, the subject matter of any of the Examples herein may optionally include wherein the hearing device or electronic device is a BTE hearing aid, is an MC hearing aid, used in circuitry in a hearing device configured to be placed within an ear of a wearer, is an in-the-canal hearing aid, is a completely-in-the-canal hearing aid, is an invisible-in-the-canal hearing aid, comprises hearing aid electronics programmed to compensate for a patient's hearing deficit.

It is understood that digital hearing aids may include a processor. In digital hearing aids with a processor, programmable gains may be employed to adjust the hearing aid output to a wearer's particular hearing impairment. The processor may be a digital signal processor (DSP), microprocessor, microcontroller, other digital logic, or combinations thereof. The processing may be done by a single processor, or may be distributed over different devices. The processing of signals referenced in this application can be performed using the processor or over different devices. Processing may be done in the digital domain, the analog domain, or combinations thereof. Processing may be done using subband processing techniques. Processing may be done using frequency domain or time domain approaches. Some processing may involve both frequency and time domain aspects. For brevity, in some examples drawings may omit certain blocks that perform frequency synthesis, frequency analysis, analog-to-digital conversion, digital-to-analog conversion, amplification, buffering, and certain types of filtering and processing. In various embodiments the processor is adapted to perform instructions stored in one or more memories, which may or may not be explicitly shown. Various types of memory may be used, including volatile and nonvolatile forms of memory. In various embodiments, the processor or other processing devices execute instructions to perform a number of signal processing tasks. Such embodiments may include analog components in communication with the processor to perform signal processing tasks, such as sound reception by a microphone, or playing of sound using a receiver (i.e., in applications where such transducers are used). In various embodiments, different realizations of the block diagrams, circuits, and processes set forth herein can be created by one of skill in the art without departing from the scope of the present subject matter.

It is further understood that different hearing assistance devices may embody the present subject matter without departing from the scope of the present disclosure. The devices depicted in the figures are intended to demonstrate the subject matter, but not necessarily in a limited, exhaustive, or exclusive sense. It is also understood that the present subject matter can be used with a device designed for use in the right ear or the left ear or both ears of the wearer.

The present subject matter is demonstrated for hearing devices, including but not limited to headsets, speakers, cochlear devices, bone conduction devices, personal listening devices, headphones, and hearing aids. Hearing aids include, but not limited to, behind-the-ear (BTE), in-the-ear (ITE), in-the-canal (ITC), receiver-in-canal (RIC or RITE), completely-in-the-canal (CIC), or invisible-in-the-canal (IIC) type hearing aids. It is understood that behind-the-ear type hearing aids may include devices that reside substantially behind the ear or over the ear. Such devices may include hearing aids with receivers associated with the electronics portion of the behind-the-ear device (BTE), or hearing aids of the type having receivers in the ear canal of the user, such as receiver-in-canal (RIC) or receiver-in-the-ear (RITE) designs.

This application is intended to cover adaptations or variations of the present subject matter. It is to be understood that the above description is intended to be illustrative, and not restrictive. The scope of the present subject matter should be determined with reference to the appended claims, along with the full scope of legal equivalents to which such claims are entitled.

1. An electronic device, comprising:
a first die;
a second die;
a printed circuit board (PCB) substrate;
wherein the first die is stacked on top of the second die to form a die stack, wherein the first and second dies are electrically connected; and,
wherein the die stack is embedded in a single first layer of the PCB substrate.

2. The device of claim 1 wherein a third die is embedded in a second layer of the PCB substrate.

3. The device of claim 1 wherein second die has through-silicon-vias (TSVs) incorporated therein that electrically connect the first and second dies.

4. The device of claim 1 wherein the first and second dies are placed back to back with active die side and interconnect in opposing directions to electrically connect the first and second dies.

5. The device of claim 1, wherein the electronic device is placed in a behind-the-ear hearing device.

6. The device of claim 5, wherein the hearing device is a BTE hearing aid.

7. The device of claim 5, wherein the hearing device is a RIC hearing aid.

8. The device of claim 1, wherein the electronic device is used in circuitry in a hearing device configured to be placed within an ear of a wearer.

9. The device of claim 8, wherein the hearing device is an in-the-canal hearing aid.

10. The device of claim 8, wherein the hearing device is a completely-in-the-canal hearing aid.

11. The device of claim 8, wherein the hearing device is an invisible-in-the-canal hearing aid.

12. A method for constructing an electronic device, comprising:
stacking a first die is on top of a second die to form a die stack with the first and second dies electrically connected; and,
embedding the die stack in a single first layer of a printed circuit board (PCB) substrate.

13. The method of claim 12 further comprising embedding a third die in a second layer of the PCB substrate.

14. The method of claim 12 wherein second die has through-silicon-vias (TSVs) incorporated therein that electrically connect the first and second dies.

15. The method of claim 12 wherein the first and second dies are placed back to back with active die side and interconnect in opposing directions to electrically connect the first and second dies.

16. A hearing device, comprising:
a microphone to convert an audio input into a first input signal;
processing circuitry to process the first input signal, the second input signal, or a combination thereof into an output signal;
wherein the processing circuitry comprises a first die and a second die and wherein the first die is stacked on top of the second die to form a die stack with the first and second dies are electrically connected; and,
wherein the die stack is embedded in a single first layer of a printed circuit board (PCB) substrate.

17. The device of claim 16, further comprising a third die embedded in a second layer of the PCB substrate.

18. The device of claim 16, wherein second die has through-silicon-vias (TSVs) incorporated therein that electrically connect the first and second dies.

19. The device of claim 16, wherein the first and second dies are placed back to back with active die side and interconnect in opposing directions to electrically connect the first and second dies.

20. The device of claim 16, comprising hearing aid electronics programmed to compensate for a patient's hearing deficit.
